(19) United States
(12) Patent Application Publication
(10) Pub. No.: US 2007/0084405 A1
(43) Pub. Date: Apr. 19, 2007

(54) Adaptive plasma source for generating uniform plasma

(75) Inventor: Nam-Hun Kim, Kyungki-do (KR)

Correspondence Address: LADAS & PARRY LLP, 224 SOUTH MICHIGAN AVENUE, SUITE 1600, CHICAGO, IL, 60604, US

(73) Assignee: ADAPTIVE PLASAMA TECHNOLOGY CORPORATION, Kyungki-do (KR)

(21) Appl. No.: 10/570,942

(22) PCT Filed: Sep. 8, 2004
(86) PCT No.: PCT/KR04/02282

§ 371 Date: Mar. 8, 2006

(30) Foreign Application Priority Data
Sep. 9, 2003 (KR) 10-2003-0063416

(51) Int. Cl. C23F 1/00; C23C 16/00

(52) U.S. Cl. 118/723 I; 156/345.48

(57) ABSTRACT

There is provided an adaptive plasma source, which is arranged at an upper portion of a reaction chamber having a reaction space to form plasma and is supplied with RF (radio frequency) power from an external RF power source to form an electric field inside the reaction space. The adaptive plasma source includes a conductive bushing and at least two unit coils. The bushing is coupled to the RF power source and arranged at an upper central portion of the reaction chamber. The at least two unit coils are branched from the bushing and surround the bushing in a spiral shape and have the number of turns equal to a×(b/m), where a and b are positive integers and m is the number of the unit coils.

### TECHNICAL FIELD

The present invention relates to plasma semiconductor process, and more particularly, to an adaptive plasma source for generating uniform plasma inside a plasma reaction chamber.

### BACKGROUND ART

Technologies for fabricating ultra-large scale integration (ULSI) circuit devices have remarkably developed during the last 20 years. Owing to semiconductor fabrication pieces of equipment using cut-edge technologies. A plasma reaction chamber, one of the semiconductor fabrication pieces of equipment, is used in a deposition process as well as an etching process and its application has widely increased.

Plasma is formed inside the plasma reaction chamber and used in an etching process, a deposition process, and the like. Based on plasma sources, plasma reaction chambers are classified into various types: an electron cyclotron resonance (ECR) plasma source, a helicon-wave-excited plasma (HWEP) source, a capacitively coupled plasma (CCP) source, and an inductively coupled plasma (ICP) source. In case of the ICP source, a magnetic field is generated by radio frequency (RF) power supplied to an inductive coil. Then, due to an electric field induced by the magnetic field, electrons are captured at an inner center of the chamber such that high density plasma is generated even at low pressure. Compared with the ECR plasma source or the HWEP source, the ICP source is simple in structure and a large area plasma can be easily obtained. Thus, the ICP source is widely used.

In a plasma chamber using the ICP source, a large RF current flows through a coil of an inductor of a resonance circuit. The RF current has a great influence on a distribution of plasma generated inside the chamber. It is well known that a coil of an inductor has a self-resistance. Accordingly, when a current flows along the coil, energy is dissipated due to the self-resistance and changed into heat. As a result, the amount of current flowing in the coil decreases gradually. Like this, if the amount of current becomes ununiform, a distribution of plasma generated inside the chamber also becomes ununiform.

FIG. 1 is a graph illustrating a plasma density (ni) distribution and a variation distribution of a critical dimension (CD) in a plasma chamber. Hereinafter, the variation will be referred to as Δ CD. In this specification, Δ CD is defined by a difference between an expected CD before a process and a resultant CD after the process.

Referring to FIG. 1, a curve 12 represents plasma density (ni). The plasma density (ni) is highest at a center of a wafer and decreases toward an edge portion of the wafer. A curve 14 represents Δ CD. Due to the nonuniformity of the plasma density ni, Δ CD decreases as from the center of the wafer toward the edge portion thereof.

Till now, problems that occur due to the nonuniformity of the plasma have been solved in a manufacturing process. However, due to various factors such as a limit of a lithography process, there is a limit in solving these problems.

### BRIEF DESCRIPTION OF THE DRAWINGS

FIG. 1 is a graph illustrating a plasma density distribution and a variation distribution of Δ CD in a plasma chamber;

FIG. 2 is a sectional view of a plasma reaction chamber employing an adaptive plasma source according to an embodiment of the present invention;

FIG. 3 is a plan view of the adaptive plasma source shown in FIG. 2;

FIGS. 4A and 4B are views for explaining an adaptive plasma source according to another embodiment of the present invention;

FIGS. 5A and 5B are views for explaining an adaptive plasma source according to a further another embodiment of the present invention;

FIG. 6 is a view for explaining an adaptive plasma source according to a further another embodiment of the present invention;

FIG. 7 is a view for explaining an adaptive plasma source according to a further another embodiment of the present invention;

FIG. 8 is an equivalent circuit diagram of an inductance component of the adaptive plasma source shown in FIG. 8; and

FIGS. 9A and 9B are views illustrating an adaptive plasma source having angular shapes according to a further another embodiment of the present invention.

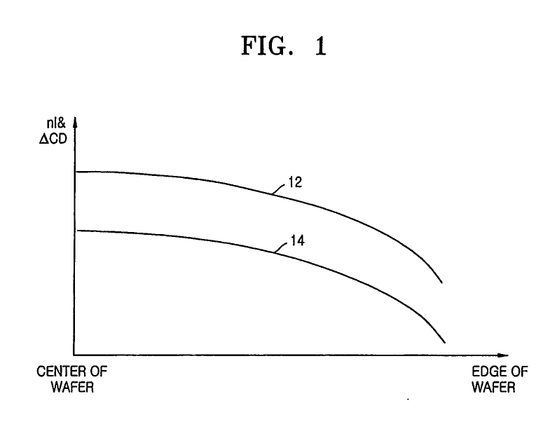

### DETAILED DESCRIPTION OF THE INVENTION

### Technical Goal of the Invention

The present invention provides an adaptive plasma source that forms uniform plasma inside a plasma reaction chamber.

### Disclosure of the Invention

According to an aspect of the present invention, there is provided an adaptive plasma source arranged at an upper portion of a reaction chamber having a reaction space to form plasma and supplied with RF (radio frequency) power from an external RF power source to form an electric field inside the reaction space. The adaptive plasma source includes: a conductive bushing coupled to the RF power source and arranged at an upper central portion of the reaction chamber; and at least two unit coils branched from the bushing, the unit coils surrounding the bushing in a spiral shape and having a number of turns equal to a×(b/m), where a and b are positive integers and m is the number of the unit coils.

The bushing may have a circular shape with a predetermined diameter and the unit coils may be branched from positions that are mutually symmetrical at edges of the busing.

The bushing may have a polygonal shape and the unit coils may have the same polygonal shape as the bushing and spirally surround the bushing.

In this case the bushing and the unit coils may have a rectangular shape. Alternatively, the bushing and the unit coils may have a hexagonal shape.

The bushing may be arranged on the same plane as the unit coils arranged on the upper portion of the reaction chamber.

The bushing may be arranged on a second plane located higher than a first plane on which the unit coils arranged on the upper portion of the reaction chamber are disposed.

In this case the unit coils may be branched from the bushing, arranged on the second plane, and extended to the first plane and then arranged on the first plane in a spiral shape.

According to another aspect of the present invention, there is provided an adaptive plasma source arranged at an upper portion of a reaction chamber having a reaction space to form plasma and supplied with RF (radio frequency) power from an external RF power source to form an electric field inside the reaction space, the adaptive plasma source including: a first conductive bushing arranged at an upper central portion of the reaction chamber on a first plane disposed on an upper portion of the reaction chamber; at least two first unit coils branched from the first bushing on the first plane, the first unit coils surrounding the first bushing in a spiral shape and having a number of turns equal to a×(b/m1), where a and b are positive integers and m1 is the number of the first unit coils; a second conductive bushing arranged corresponding to the first bushing on a second plane located higher than the first plane, the second conductive bushing being elastically connected to the first bushing; and at least two second unit coils branched from the second bushing on the second plane, the second unit coils surrounding the second bushing in a spiral shape and having a number of turns equal to a×(b/m2), where a and b are positive integers and m2 is the number of the second unit coils.

The first bushing may have a cross section equal to or wider than that of the second bushing.

The adaptive plasma source may further include: at least one third bushing coupled to the first and second bushings on at least one plane between the first plane and the second plane; and at least one third unit coil branched from the third bushing and arranged in the same manner as the first unit coils and the second unit coils.

### Effect of the Invention

According to the adaptive plasma source of the present invention, unit coils are arranged around a bushing in a spiral shape based on a predetermined rule so that the coil arrangement can be symmetrical in any position. Thus, a uniform plasma density can be achieved. Also, due to the bushing disposed at a central portion, plasma density decreases at the central portion having a relatively strong plasma density, such that the plasma density is entirely distributed uniformly. Further, the bushing and the unit coils are arranged at upper and lower portions, such that a total impedance can be finely adjusted by controlling the number and the number of turns of the unit coils.

### BEST MODE FOR CARRYING OUT THE INVENTION

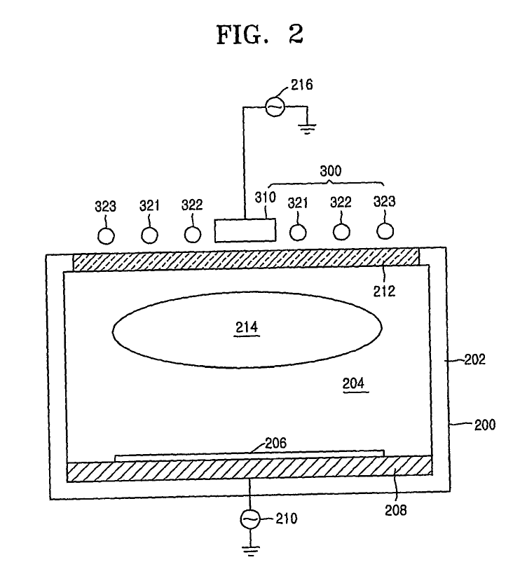

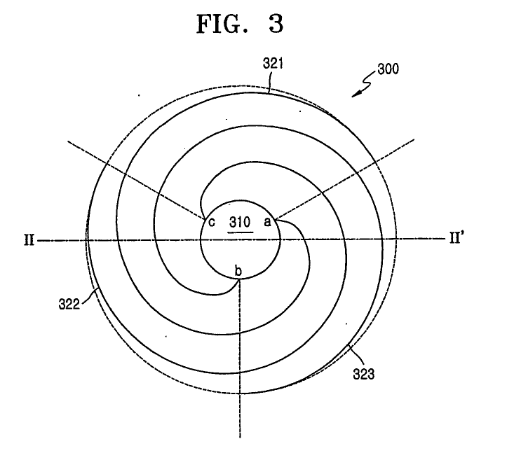

FIG. 2 is a sectional view of a plasma reaction chamber employing an adaptive plasma source according to an embodiment of the present invention, and FIG. 3 is a plan view of the adaptive plasma source shown in FIG. 2.

Referring to FIG. 2, a plasma reaction chamber 200 includes an inner space 204 of a predetermined volume, which is defined by a chamber outer wall 202. An object to be processed, for example a semiconductor wafer 206, is disposed at a lower portion of the inner space 204 of the plasma reaction chamber 200. The semiconductor wafer 206 is placed on a susceptor 208 installed in a lower portion of the plasma reaction chamber 200. The support member 208 is coupled to an RF power source 210 supplied from outside of the plasma reaction chamber 200. A dome 212 is disposed at an upper portion of the plasma reaction chamber 200. Plasma 214 is formed in a space between the dome 212 and the semiconductor wafer 206.

An adaptive plasma source 300 for the plasma 214 is disposed above the dome 212 and spaced apart from the dome 212 by a predetermined distance. The adaptive plasma source 300 includes a bushing 310 and a plurality of unit coils 321, the bushing 310 being disposed in the middle of the unit coils 321. The bushing 310 is coupled to an RF power source 216. RF power is supplied to the unit coils 321, 322 and 323 from the RF power source 216 and the unit coils 321, 322 and 323 generate electric fields. The electric fields are induced to the inner space 204 through the dome 212. The electric fields induced to the inner space 204 produces a gas in discharge of the inner space 204, thereby making the plasma 214. Neutral radical particles and charged ions, which are generated when the plasma 214 is produced, chemically react with one another.

Referring to FIG. 3, the adaptive plasma source 300 generating the plasma 214 inside the inner space 204 of the plasma reaction chamber 200 has a structure in that the plurality of unit coils 321, 322 and 323 branched from the bushing 310 disposed at the center spirally surround the bushing 310. Although the bushing 310 has a circular shape, it can also have other shapes. For example, the bushing 310 may have a polygonal shape, such as a triangle, or a circular or polygonal donut shape. The busing 310 is disposed corresponding to the center of the plasma reaction chamber. Accordingly, the plasma density at the center of the plasma reaction chamber can be decreased.

Branched points a, b and c where the unit coils 321, 322 and 323 and the bushing 310 are coupled together are mutually symmetrical with one another. Because the unit coils 321, 322 and 323 must be supplied with the RF power 216 from the RF power source 216 through the bushing 310, the bushing 310 is partially or entirely made of a conductive material. Although FIG. 3 shows that the number of the unit coils and the number of turns of each unit coil are respectively three and one, the number of the unit coils may be two or more that four. Also, the number of turns of the unit coil may be given as an Equation 1 below.
n=a×(b/m) [Equation 1]

where, “n” denotes the number of turns of each unit coil, “a” and “b” denote positive integers, and “m” denotes the number of unit coils.

According to Equation 1, because the number m of the unit coils 321, 322 and 323 shown in FIG. 3 is “3”, the number n of turns of each unit coil may be ⅓, ⅔, 1, 1 and ⅓, 1 and ⅔, and so on. When these conditions are satisfied, the unit coils 321, 322 and 323 are arranged symmetrically in any positions. Thus, uniform plasma density can be obtained. That is, even when the adaptive plasma source 300 is cut away along any one of the lines passing through the center of the bushing 310, each unit coil is bilaterally symmetric. However, when the conditions of Equation 1 are not satisfied, each unit coil may be asymmetric. For example, while three unit coils are all arranged on a right side of the bushing, only two unit coils may be arranged on a left side. Such an asymmetric arrangement may be one of the factors that leads to the nonuniform plasma density inside the inner space of the plasma reaction chamber.

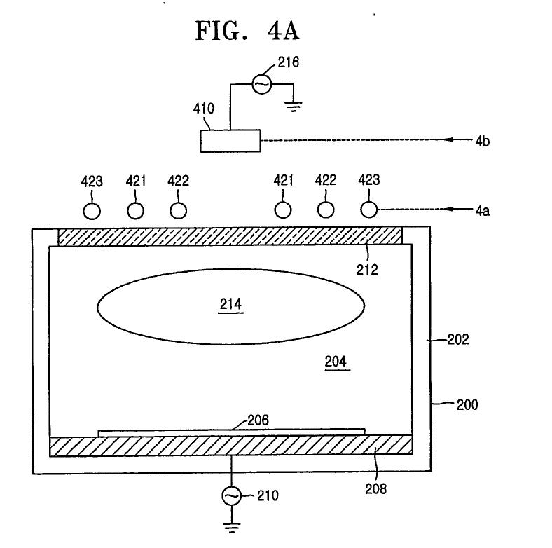

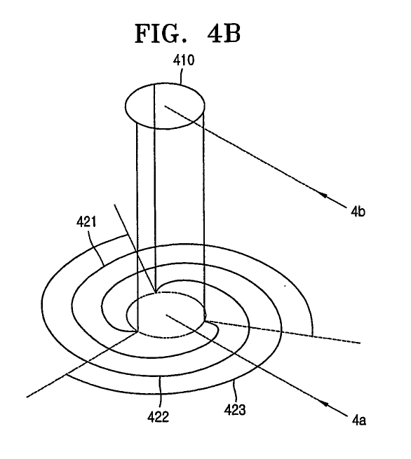

FIGS. 4A and 4B are views of an adaptive plasma source according to another embodiment of the present invention. In detail, FIG. 4A is a view of a structure in which an adaptive plasma source is attached to a plasma reaction chamber, and FIG. 4B is a three-dimensional view of the adaptive plasma source shown in FIG. 4A. Since the same reference symbols are used to refer to the same elements as in FIGS. 2 and 4, descriptions thereof will be omitted.

Referring to FIGS. 4A and 4B, an adaptive plasma source includes a bushing 410 disposed at an upper portion and two or more (for example three) unit coils 421, 422 and 423 disposed at a lower portion. The unit coils 421, 422 and 423 are disposed on a first plane 4a that is adjacent to an upper surface of a dome 212 of a plasma reaction chamber 200. The bushing 410 is disposed on a second plane 4b that is relatively further spaced apart from the upper surface of the dome 212. Specifically, the unit coils 421, 422 and 423 branched from the bushing 410 on the second plane 4b extend vertically to the first plane 4a. Each of the unit coils 421, 422 and 423 extending to the first plane 4a is arranged on the first plane 4a in a spiral shape. Since the spiral structure of the unit coils 421, 422 and 423 is identical as described in FIG. 3, its description will be omitted.

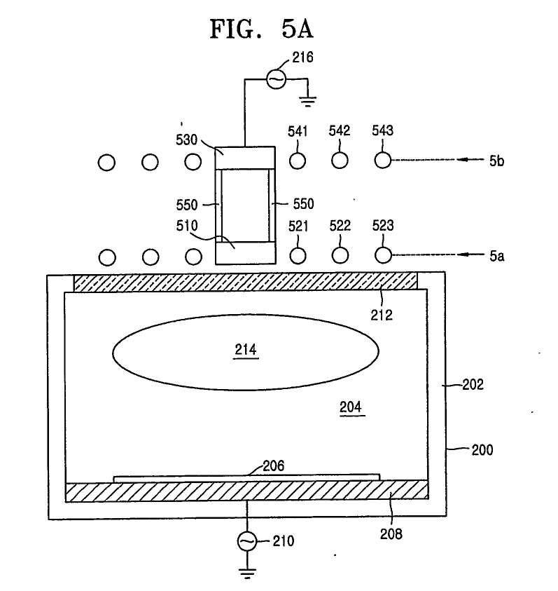

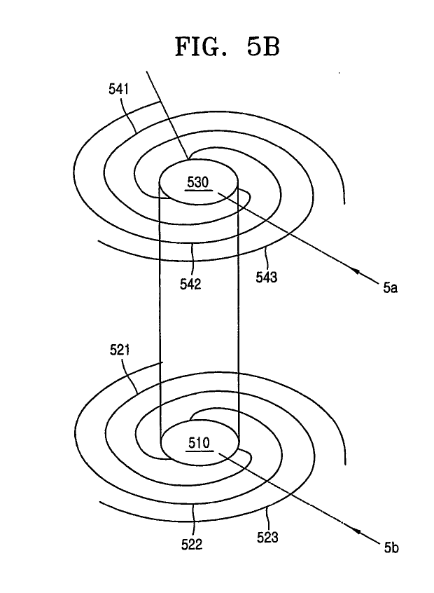

FIGS. 5A and 5B are views of an adaptive plasma source according to a further another embodiment of the present invention. In detail, FIG. 5A is a view of a structure in which an adaptive plasma source is attached to a plasma reaction chamber, and FIG. 5B is a three-dimensional view of the adaptive plasma source shown in FIG. 5A. Since the same reference symbols are used to refer to the same elements in FIGS. 2 and 5A, descriptions thereof will be omitted.

Referring to FIGS. 5A and 5B, an adaptive plasma source includes a first bushing 510 disposed at a lower portion and a second bushing 530 disposed at an upper portion. The first bushing 510 is arranged on a first plane 5a that is located on an upper surface of a dome 212 of a plasma reaction chamber 200, and the second bushing 530 is arranged on a second plane 5b that is located higher than the first plane 5a by a predetermined distance. In addition to the first busing 510, two or more (for example three) first unit coils 521, 522 and 523 are arranged on the first plane 5a. Likewise, in addition to the second busing 530, two or more (for example three) second unit coils 541, 542 and 543 are arranged on the second plane 5b. The first busing 510 and the second busing 530 are coupled through a coupling rod 550. The coupling rod 550 is made of a conductive material. Thus, RF power can be supplied to the first bushing 510 through the second bushing 530 and the coupling rod 550.

The first unit coils 521, 522 and 523 are branched from the first bushing 510 and surround the first bushing 510 on the first plane 5a in a spiral shape. The second unit coils 541, 542 and 543 are branched from the second bushing 530 and surround the second bushing 530 on the second plane 5b in a spiral shape. Since the structures of the first and second unit coils are identical as described in FIG. 3, their description will be omitted.

Although not shown in the drawings, at least one bushing arranged in the same manner as the first and second bushings 510 and 530 can be further provided on a predetermined plane between the first plane 5a and the second plane 5b. At least two unit coils (not shown) can be arranged from the bushing in the same manner as the first and second unit coils. Also, the number of the first unit coils may be equal to or different from that of the second unit coils.

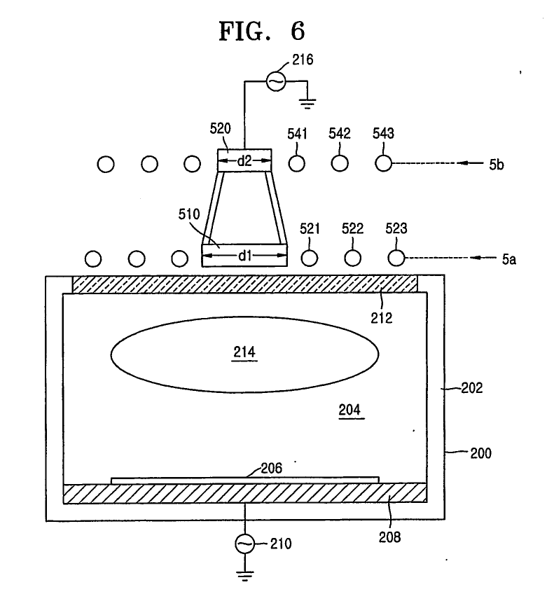

FIG. 6 is a view of an adaptive plasma source according to a further another embodiment of the present invention.

Referring to FIG. 6, an adaptive plasma source includes a first bushing 510 disposed at a lower portion and a second bushing 540 disposed at an upper portion. Unlike the adaptive plasma source of FIG. 5A, the adaptive plasma source of FIG. 6 is characterized in that a diameter d1 of the first bushing 510 is different from a diameter d2 of the second bushing 540. That is, the diameter d1 of the first bushing 510 on a first plane 5a is larger than the diameter d2 of the second bushing 540 on a second plane 5b. This means that a cross section of the first bushing 510 is wider than that of the second bushing 540. This structure is obtained by extending the diameter d1 of the first busing 510 and is more effective in decreasing a plasma density at a central portion of the plasma reaction chamber 200. In other words, as the plasma reaction chamber's region overlapping with the first unit coils 521, 522 and 523 is decreasing, a region at which the plasma density decreases is widened.

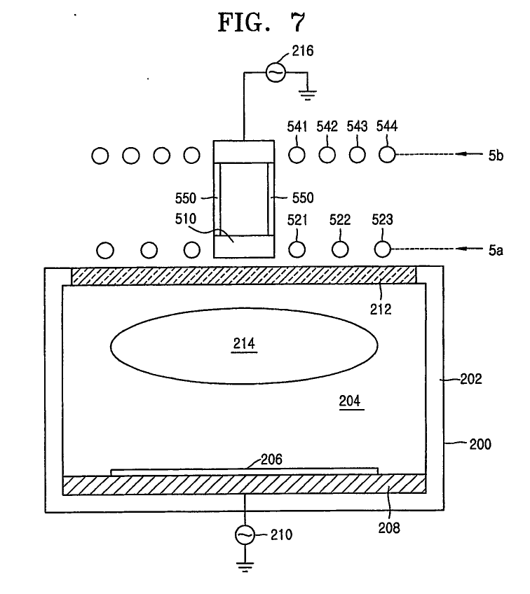

FIG. 7 is a view of an adaptive plasma source according a further another embodiment of the present invention.

Referring to FIG. 7, a difference from the adaptive plasma source of FIG. 5 is that the number of the first unit coils 521, 522 and 523 is not equal to that of the second unit coils 541, 542, 543 and 544. That is, while the number of the first unit coils 521, 522 and 523 disposed at the lower portion is three, the number of the second unit coils 541, 542, 543 and 544 is four. A more fine impedance can be obtained by adjusting the number of the lower unit coils and the number of the upper unit coils.

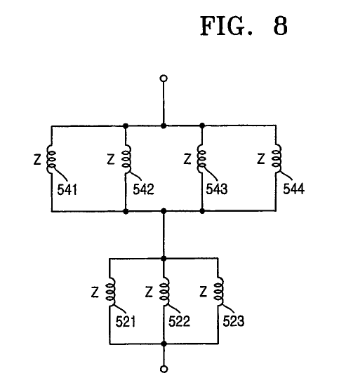

FIG. 8 is an equivalent circuit diagram of an inductance component of the adaptive plasma coil shown in FIG. 7.

Referring to FIG. 8, all the first unit coils 521, 522 and 523 disposed at the lower portion are branched from the first bushing 510, resulting in a parallel circuit configuration. Also, all the second unit coils 541, 542, 543 and 544 disposed at the upper portion are branched from the second bushing 530, resulting in a parallel circuit configuration. If the respective unit coils have equal impedance Z, a second equivalent impedance Z2 of the second unit coil circuit becomes Z/4. Likewise, a first equivalent impedance Z1 of the first unit coil circuit becomes Z/3. Thus, a total equivalent impedance Zt is 7Z/12, which is the sum of the first equivalent impedance Z1 and the second equivalent impedance Z2. That is, an equivalent impedance corresponding to 7/12 time impedance of one unit coil can be obtained. Accordingly, a more fine impedance can be obtained. For example, when three unit coils and four unit coils are respectively arranged at the lower portion and the upper portion, 1/12- 12/12 time impedance of one unit coil can be obtained.

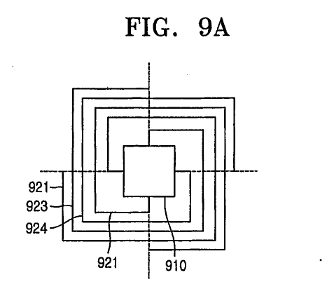

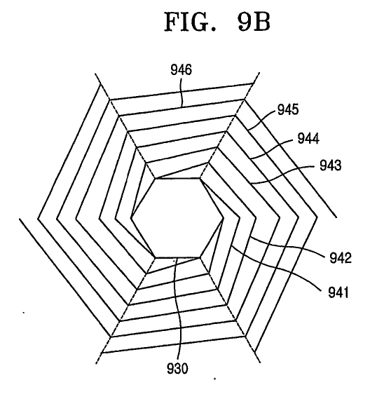

FIGS. 9A and 9B are views of adaptive plasma sources having angular shapes according to a further another embodiment of the present invention.

Although the circular bushing has been described above, the bushing can also be formed in an angular shape. As shown in FIGS. 9A and 9B, the bushing can be formed in a rectangular shape or a hexagonal shape. In case of the rectangular bushing 910 shown in FIG. 9A, two or more (for example four) unit coils 921, 922, 923 and 924 are symmetrically branched from four sides of the bushing 910. In this case, it is apparent that the unit coils can be branched from four corners of the bushing 910. Also, the number of turns of the unit coils 921, 922, 923 and 924 is determined by the above Equation 1. That is, because four unit coils 921, 922, 923 and 924 are used, the number of turns becomes ¼, 2/4, ¾, 1, 1 and ¼, 1 and 2/4, and so on. In case of the hexagonal bushing 930 shown in FIG. 9B, two or more (for example six) unit coils 941, 942, 943, 944, 945 and 946 are symmetrically branched from six corners of the bushing 930. The number of turns of the unit coils 941, 942, 943, 944, 945 and 946 is also determined by Equation 1. That is, because six unit coils 941, 942, 943, 944, 945 and 946 are used, the number of turns becomes ⅙, 2/6, 3/6, 4/6, ⅚, 1, 1 and ⅙, 1 and 2/6, 1 and 3/6, 1 and 4/6, and so on.

1. An adaptive plasma source arranged at an upper portion of a reaction chamber having a reaction space to form plasma and supplied with RF (radio frequency) power from an external RF power source to form an electric field inside the reaction space, the adaptive plasma source comprising:
a conductive bushing coupled to the RF power source and arranged at an upper central portion of the reaction chamber; and
at least two unit coils branched from the bushing, the unit coils surrounding the bushing in a spiral shape and having the number of turns equal to a×(b/m), where a and b are positive integers and m is the number of the unit coils.

2. The adaptive plasma source of claim 1, wherein the bushing has a circular shape with a predetermined diameter and the unit coils are branched from positions that are mutually symmetrical at edges of the busing.

3. The adaptive plasma source of claim 1, wherein the bushing has a polygonal shape, and the unit coils have the same polygonal shape as the bushing and spirally surround the bushing.

4. The adaptive plasma source of claim 3, wherein the bushing and the unit coils have a rectangular shape.

5. The adaptive plasma source of claim 3, wherein the bushing and the unit coils have a hexagonal shape.

6. The adaptive plasma source of claim 1, wherein the bushing is arranged on the same plane as the unit coils arranged on the upper portion of the reaction chamber.

7. The adaptive plasma source of claim 1, wherein the bushing is arranged on a second plane located higher than a first plane on which the unit coils arranged on the upper portion of the reaction chamber are disposed.

8. The adaptive plasma source of claim 7, wherein the unit coils are branched from the bushing arranged on the second plane and are extended to the first plane and then arranged on the first plane in a spiral shape.

9. An adaptive plasma source arranged at an upper portion of a reaction chamber having a reaction space to form plasma and supplied with RF (radio frequency) power from an external RF power source to form an electric field inside the reaction space, the adaptive plasma source comprising:
a first conductive bushing arranged at an upper central portion of the reaction chamber on a first plane disposed on an upper portion of the reaction chamber;
at least two first unit coils branched from the first bushing on the first plane, the first unit coils surrounding the first bushing in a spiral shape and having the number of turns equal to a×(b/m1), where a and b are positive integers and m1 is the number of the first unit coils;
a second conductive bushing arranged corresponding to the first bushing on a second plane located higher than the first plane, the second conductive bushing being elastically connected to the first bushing; and
at least two second unit coils branched from the second bushing on the second plane, the second unit coils surrounding the second bushing in a spiral shape and having the number of turns equal to a×(b/m2), where a and b are positive integers and m2 is the number of the second unit coils.

10. The adaptive plasma source of claim 9, wherein the first bushing has a cross section equal to or wider than that of the second bushing.

11. The adaptive plasma source of claim 9, further comprising:
at least one third bushing coupled to the first and second bushings on at least one plane between the first plane and the second plane; and
at least one third unit coil branched from the third bushing and arranged in the same manner as the first unit coils and the second unit coils.
